(19) United States
(12) Patent Application Publication
(10) Pub. No.: US 2012/0242376 A1
(43) Pub. Date: Sep. 27, 2012

(54) LOAD DRIVE APPARATUS AND SEMICONDUCTOR SWITCHING DEVICE DRIVE APPARATUS

(75) Inventors: Tomohisa OSE, Nukata-gun (JP); Yoshiyuki Hamanaka, Kariya-city (JP); Yasutaka Senda, Nukata-gun (JP); Ryotaro Miura, Nukata-gun (JP); Kenji Yamamoto, Okazaki-city (JP)

(73) Assignee: DENSO CORPORATION, Kariya-city (JP)

(21) Appl. No.: 13/426,949

(22) Filed: Mar. 22, 2012

(30) Foreign Application Priority Data
Mar. 24, 2011 (JP) 2011-66221
Apr. 12, 2011 (JP) 2011-88017

(51) Int. Cl. H03K 17/08

(52) U.S. Cl. 327/109

(57) ABSTRACT

A load drive apparatus includes a switching device, a gate drive circuit, a clamp circuit, a temperature detection circuit, and an arithmetic device. The switching device controls an on-off state of current supply to a load. The gate drive circuit turns on the switching device by controlling a gate voltage of the switching device so that the switching device operates in a full-on state. The clamp circuit clamps the gate voltage of the switching device to a clamp voltage lower than the gate voltage in the full-on state and higher than a mirror voltage. The temperature detection circuit detects a temperature of the switching device. The arithmetic device calculates a voltage corresponding to a variation in a mirror voltage based on the detected temperature and controls the clamp voltage in the clamp circuit so as to be the calculated voltage.

### CROSS REFERENCE TO RELATED APPLICATIONS

The present application is based on and claims priority to Japanese Patent Applications No. 2011-66221 filed on Mar. 24, 2011 and No. 2011-88017 filed on Apr. 12, 2011, the contents of which are incorporated in their entirety herein by reference.

### TECHNICAL FIELD

The present disclosure relates to a load drive apparatus that includes a switching device for controlling current supply to a load. The present disclosure also relates to a semiconductor switching device drive apparatus.

### BACKGROUND

There has been provided a load drive apparatus that drives a load using a switching device such as an insulated gate bipolar transistor (IGBT) and a power metal-oxide semiconductor field-effect transistor (power MOSFET). When an IGBT is turned on, if a short circuit occurs somewhere on a line for power supply to a load coupled with the IGBT, the load drive apparatus generates an overcurrent, and the IGBT is broken down due to a sudden rise in temperature of the IGBT. Thus, detection of the short circuit is important.

In the load drive apparatus, the IGBT size is reduced for IGBT cost reduction, and the short circuit capacity of IGBT devices is structurally decreases. When a short circuit failure occurs, an overcurrent may be continuously applied to the IGBT and the IGBT may be broken down due to a sudden rise in the temperature. The short circuit capacity means the time (or energy) from the beginning of the overcurrent application to the breakdown. When the short circuit capacity is low, the time to the breakdown shortens. In a configuration that protects a device after detection of a short circuit, it may take a time from detection of the short circuit to protection of the device and the device may not be protected sufficiently due to a low short circuit capacity.

To solve the above-described issue, an IGBT gate voltage is clamped to a clamp voltage when the IGBT turns on. Accordingly, the IGBT is restricted from being broken down due to a high current generated at a short circuit. The clamp voltage needs to be higher than a gate voltage (hereafter, referred to as a mirror voltage) due to the IGBT mirror effect and therefore must be designed in consideration of a maximum variation in the mirror voltage. FIG. 23A is a timing diagram showing an IGBT operation in a normal operation. FIG. 23B is a timing diagram showing an IGBT operation in a short-circuit operation. As shown in FIG. 23A, the mirror voltage greatly varies, for example, with the IGBT environment. The clamp voltage is set to a voltage larger than the maximum mirror voltage. The clamp is released and a full on-state is enabled if a short circuit detection circuit performs a short circuit determination and detects a normal result. As shown in FIG. 23B, when the short circuit detection circuit performs a short circuit determination and detects a short circuit, the clamp is maintained and soft disconnection is performed after a predetermined time period. Accordingly, a high current due to the short circuit can be restricted from flowing.

Various methods of driving an IGBT by changing a gate voltage are disclosed. For example, JP-A-2009-71956 (corresponding to US 2009/0066402 A1) describes a two-stage voltage drive system that changes a gate voltage. JP-A-2009-11049 (corresponding to US 2009/0002054 A1) describes a constant current changeover system that changes a constant current drive circuit and a voltage drive circuit.

However, because the clamp voltage is designed in consideration of a maximum variation value in the mirror voltage, the clamp voltage has to be set to a large value. This is disadvantageous to the short circuit capacity because a current flows during the short circuit.

JP-A-2008-29059 proposes a drive circuit that drives an IGBT. Specifically, the drive circuit proposed in JP-A-2008-29059 includes the IGBT whose control terminal (gate) is coupled with a first drive circuit for supplying a first current, a second drive circuit for supplying a second current, and a voltage motor for detecting a voltage value at the control terminal.

According to the drive circuit, only the first drive circuit supplies the first current to the IGBT control terminal if the voltage at the control terminal is lower than a threshold voltage. A second current in addition to the first current is supplied to the control terminal if the voltage at the control terminal reaches the threshold voltage. When the IGBT is activated, the drive circuit decreases a variation in the current between a collector and an emitter and shortens the period of a mirror region in which a voltage at the control terminal is constant.

JP-A-2008-29059 also proposes a configuration in which a temperature monitor and peripheral circuit components are disposed in the same semiconductor module. By monitoring a temperature, a switching loss in use at a high temperature can be restricted.

However, in the above-described conventional technique, a temperature change in the IGBT varies a surge voltage that may occur during switching operations even though the temperature monitor detects the temperature. When the temperature changes, an overvoltage may occur and may break the IGBT.

As is generally known, increasing a drive current applied to the IGBT control terminal increases a turn-on slew rate for the control terminal voltage and increases a switching speed. JP-A-2001-169407 (corresponding to US 2007/0002782) discloses that in a relationship between an IGBT temperature and the allowable surge breakdown voltage, a lower-temperature region indicates a smaller allowable surge breakdown voltage than a higher-temperature region.

It might be possible to predetermine a small drive current in order to provide a small turn-on slew rate in anticipation of a surge voltage when the IGBT temperature changes. However, decreasing a drive current applied to the control terminal decreases the switching speed and increases a switching loss.

There has been described the drive circuit that drives the IGBT as a semiconductor switching device. Obviously, the IGBT is an example of devices. The above-mentioned issue may also occur in other semiconductor switching devices.

### SUMMARY

It is an object of the present disclosure to provide a load drive apparatus that can improve a short circuit capacity and can restrict increase in a loss. Another object of the present disclosure is to provide a semiconductor switching device drive apparatus that can restrict occurrence and variation of a surge voltage due to a temperature change in a semiconductor switching device and can decrease a switching loss.

A load drive apparatus according to a first aspect of the present disclosure includes a switching device, a gate drive circuit, a clamp circuit, a temperature detection circuit, and an arithmetic device. The switching device controls an on-off state of current supply to a load. The gate drive circuit turns on the switching device and supplies current to the load by controlling a gate voltage of the switching device so that the switching device operates in a full-on state where the switching device is in an unsaturated region. The clamp circuit clamps the gate voltage of the switching device to a clamp voltage lower than the gate voltage in the full-on state and higher than a mirror voltage. The temperature detection circuit detects a temperature of the switching device. The arithmetic device calculates a voltage corresponding to a variation in the mirror voltage based on the temperature detected by the temperature detection circuit and controls the clamp voltage in the clamp circuit so as to be the calculated voltage.

The load drive apparatus according to the first aspect can restrict increase in a loss while improving a short circuit capacity.

A load drive apparatus according to a second aspect of the present disclosure includes a switching device, a gate drive circuit, a clamp circuit, a current detection circuit, and an arithmetic device. The switching device controls an on-off state of current supply to a load. The gate drive circuit turns on the switching device and supplies current to the load by controlling a gate voltage of the switching device so that the switching device operates in a full-on state where the switching device is in an unsaturated region. The clamp circuit clamps the gate voltage of the switching device to a clamp voltage lower than the gate voltage in the full-on state and higher than a mirror voltage. The current detection circuit detects an output current supplied from the switching device to the load. The arithmetic device calculates a voltage corresponding to a variation in the mirror voltage based on the output current supplied from the switching device and detected by the current detection circuit and controls the clamp voltage in the clamp circuit so as to be the calculated voltage.

The load drive apparatus according to the second aspect can restrict increase in a loss while improving a short circuit capacity.

A load drive apparatus according to a third aspect of the present disclosure includes a switching device, a gate drive circuit, a clamp circuit, a mirror voltage detection circuit, and an arithmetic device. The switching device controls an on-off state of current supply to a load. The gate drive circuit turns on the switching device and supplies current to the load by controlling a gate voltage of the switching device so that the switching device operates in a full-on state where the switching device is in an unsaturated region. The clamp circuit clamps the gate voltage of the switching device to a clamp voltage lower than the gate voltage in the full-on state and higher than a mirror voltage. The mirror voltage detection circuit detects the mirror voltage by detecting a gate voltage of the switching device applied to the load. The arithmetic device calculates a voltage corresponding to a variation in the mirror voltage based on the mirror voltage detected by the mirror voltage detection circuit and controls the clamp voltage in the clamp circuit so as to be the calculated voltage.

The load drive apparatus according to the third aspect can restrict increase in a loss while improving a short circuit capacity.

A load drive apparatus according to a fourth aspect of the present disclosure includes a switching device, a gate drive circuit, a clamp circuit, a switch, a constant current source, a voltage detection circuit, and an arithmetic device. The switching device includes a first electrode and a second electrode and controls an on-off state of a currently supply line to a load when a gate voltage is controlled, the first electrode coupled to a power supply side of the current supply line, the second electrode coupled to a reference point side of the current supply line. The gate drive circuit turns on the switching device and supplies current to the load by controlling the gate voltage of the switching device so that the switching device operates in a full-on state where the switching device is in an unsaturated region. The clamp circuit clamps the gate voltage of the switching device to a clamp voltage lower than the gate voltage in the full-on state and higher than a mirror voltage. The switch short-circuits between a gate and a collector of the switching device. The constant current source generates a constant current in order to drive the switching device at a constant current. The voltage detection circuit short-circuits between the gate and the collector of the switching device using the switch, drives the switching device at the constant current generated by the constant current source, and detects a voltage between the gate and the second electrode of the switching device. The arithmetic device learns at least one of a variation in a gate threshold voltage and a variation in a current amplification factor based on the voltage between the gate and the second electrode detected by the voltage detection circuit, calculates a voltage corresponding to a variation in the mirror voltage based on a learning result, and controls the clamp voltage in the clamp circuit so as to be the calculated voltage.

The load drive apparatus according to the fourth aspect can restrict increase in a loss while improving a short circuit capacity.

A semiconductor switching device drive apparatus according to a fifth aspect of the present disclosure includes a semiconductor switching device, a drive section, a control section, and a temperature detection section. The semiconductor switching device includes a control terminal. The drive section supplies a drive current to the control terminal of the semiconductor switching device. The drive section is configured so that an on-time that elapses until the semiconductor switching device is turned on shortens with increase in magnitude of the drive current. The control section controls an on-off state of the semiconductor switching device by allowing or disallowing supply of the drive current from the drive section to the control terminal. The temperature detection section detects one of a device temperature of the semiconductor switching device and an ambient temperature of the semiconductor switching device. The drive section varies the magnitude of the drive current supplied to the control terminal in accordance with one of the device temperature and the ambient temperature detected by the temperature detection section.

The semiconductor switching device drive apparatus according to the fifth aspect can restrict occurrence and variation of a surge voltage due to a temperature change in the semiconductor switching device and can decrease a switching loss.

### BRIEF DESCRIPTION OF THE DRAWINGS

Additional objects and advantages of the present disclosure will be more readily apparent from the following detailed description when taken together with the accompanying drawings. In the drawings:

FIG. 1 is a circuit diagram showing a load drive apparatus according to a first embodiment of the present disclosure;

FIG. 2A is a circuit diagram showing a gate drive circuit in a case where the gate drive circuit is configured as a two-stage voltage drive system, and FIG. 2B is a circuit diagram showing a gate drive circuit in a case where the gate drive circuit is configured as a constant current system;

FIG. 3 is a circuit diagram showing an example of a clamp circuit according to the first embodiment;

FIG. 4 is a circuit diagram showing a clamp circuit according to a second embodiment of the present disclosure;

FIG. 5 is a circuit diagram showing a load drive apparatus according to a third embodiment of the present disclosure;

FIG. 6 is a circuit diagram showing a load drive apparatus according to a fourth embodiment of the present disclosure;

FIG. 7 is a circuit diagram showing a load drive apparatus according to a fifth embodiment of the present disclosure;

FIG. 8 is a circuit diagram showing a load drive apparatus according to a sixth embodiment of the present disclosure;

FIG. 9 is a timing diagram showing an operation of the load drive apparatus according to the sixth embodiment;

FIG. 10 is a circuit diagram showing a load drive apparatus according to a seventh embodiment of the present disclosure;

FIG. 11 is a schematic diagram showing a semiconductor switching device drive apparatus according to an eighth embodiment of the present disclosure;

FIG. 12 is a schematic diagram showing a semiconductor switching device drive apparatus in a case where a temperature-sensitive diode is used as a temperature detection section;

FIG. 13 is a circuit diagram showing the semiconductor switching device drive apparatus shown in FIG. 1;

FIG. 14 is a graph showing a relationship between a temperature and a drive current of the semiconductor switching device drive apparatus according to the eighth embodiment;

FIG. 15 is a timing diagram showing operations of the semiconductor switching device drive apparatus according to the eighth embodiment;

FIG. 16 is a circuit diagram showing a semiconductor switching device drive apparatus according to a ninth embodiment of the present disclosure;

FIG. 17 is a circuit diagram showing a semiconductor switching device drive apparatus according to a tenth embodiment of the present disclosure;

FIG. 18 is a circuit diagram showing a semiconductor switching device drive apparatus according to an eleventh embodiment of the present disclosure;

FIG. 19 is a graph showing a relationship between a temperature and a drive current of the semiconductor switching device according to the eleventh embodiment;

FIG. 20 is a circuit diagram showing a semiconductor switching device drive apparatus according to a twelfth embodiment of the present disclosure;

FIG. 21 is a graph showing a relationship between a temperature and a drive current of the semiconductor switching device according to the twelfth embodiment;

FIG. 22 is a schematic diagram showing a semiconductor switching device drive apparatus according to a thirteenth embodiment of the present disclosure; and

FIG. 23A is a timing diagram showing an IGBT operation in a normal operation according to a related art, and FIG. 23B is a timing diagram showing an IGBT operation in a short-circuit operation according to the related art.

### DETAILED DESCRIPTION

Embodiments of the present disclosure will be described in further detail with reference to the accompanying drawings. Throughout the drawings, the same or equivalent elements in more than one embodiment are designated by the same reference numerals or symbols.

### First Embodiment

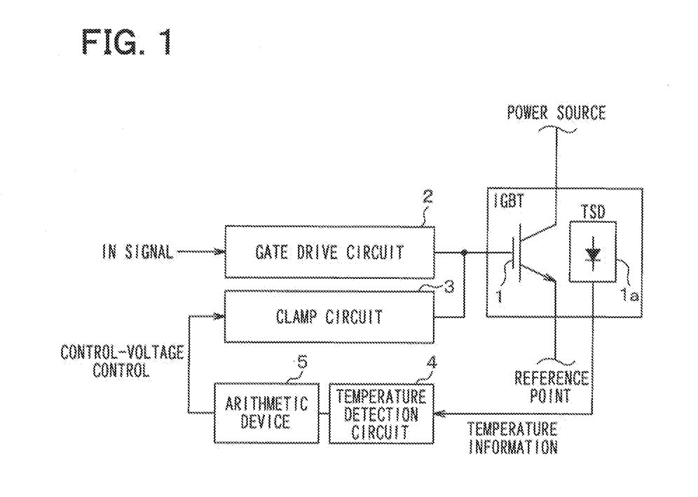

A load drive apparatus according to a first embodiment of the present disclosure will be described with reference to, for example, FIG. 1. The load drive apparatus shown in FIG. 1 includes an IGBT 1 as a switching device, a gate drive circuit 2, a clamp circuit 3, a temperature detection circuit 4, and an arithmetic device 5. The IGBT 1 is coupled with a load (not shown). The load drive apparatus enables a power supply to the load by turning on the IGBT.

The gate drive circuit 2 drives the IGBT 1. A collector of the IGBT 1 is coupled to a power source. An emitter of the IGBT 1 is used as a reference point at a predetermined potential. The load is coupled with the collector or the emitter of the IGBT 1. The load may be any apparatus that is driven in accordance with an on-off state of the power, supply. For example, when an inverter includes a plurality of IGBTs 1, a three-phase motor may be used as the load. In the present case, the load drive apparatus shown in FIG. 1 can be applied as an upper arm and a lower arm for each of the three phases. If the load drive apparatus shown in FIG. 1 is applied as the upper arm, the collector of the IGBT 1 is coupled to the power source and the emitter is coupled to the three-phase motor. If the load drive apparatus shown in FIG. 1 is applied as the lower arm, the collector of the IGBT 1 is coupled to the three-phase motor and the emitter is coupled to the ground.

A chip where the IGBT 1 is formed includes a temperature-sensitive diode (TSD) 1a as a temperature detection section. The temperature-sensitive diode 1a generates an output signal in accordance with the temperature of the IGBT 1, thereby enabling detection of the temperature of the IGBT 1. For example, the temperature-sensitive diode 1a includes a plurality of diodes coupled in series. A potential between the temperature-sensitive diode 1a and a temperature detection resistor (not shown) is generated as an output potential corresponding to the temperature of the IGBT 1. The output potential varies with temperature characteristics of forward voltage Vf of the diode. Thus, the output potential can be used as temperature information to detect the temperature of the IGBT 1.

The gate drive circuit 2 turns on the IGBT 1 to control power supply to the load. Specifically, the gate drive circuit 2 receives an IN signal as a control signal for driving the IGBT 1 from a control section such as a microcomputer (not shown). The gate drive circuit 2 controls the IGBT 1 based on the IN signal and thereby controlling current supply to the load. The gate drive circuit 2 may be configured as either of the following systems. One is the two-stage voltage drive system that changes the gate voltage to a clamp voltage and a larger voltage capable of a full-on state. The other is the constant current system that uses a constant current drive circuit to keep a constant current supplied to the gate.

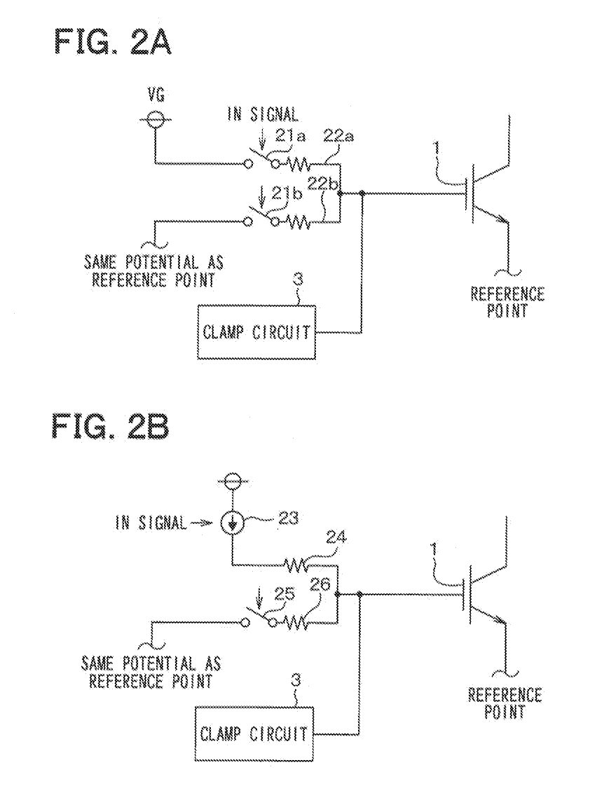

FIG. 2A is a circuit diagram showing the gate drive circuit 2 in a case where the gate drive circuit 2 is configured as the two-stage voltage drive system. The gate drive circuit 2 includes an on-circuit and an off-circuit. The on-circuit includes a switch 21a and a resistor 22a coupled in series. The off-circuit includes a switch 21b and a resistor 22b coupled in series. An IN signal from the microcomputer controls on-off states of the switches 21a and 21b. To turn on the IGBT 1, gate voltage VG is applied to the gate of the IGBT 1 via the on-circuit. To turn off the IGBT 1, the gate of the IGBT 1 is coupled to the ground via the off-circuit.

FIG. 2B is a circuit diagram showing the gate drive circuit 2 in a case where the gate drive circuit 2 is configured as the constant current system. The gate drive circuit 2 includes an on-circuit and an off-circuit. The on-circuit includes a constant current source 23 and a resistor 24 coupled in series. The off-circuit includes a switch 25 and a resistor 26 coupled in series. To turn on the IGBT 1, the constant current source 23 of the on-circuit generates a constant current based on an IN signal from the microcomputer. The constant current is supplied to the gate of the IGBT 1. To turn off the IGBT 1, the gate of the IGBT 1 is coupled to the ground via the off-circuit.

The gate drive circuit 2 may be configured as the two-stage voltage drive system or the constant current system. FIG. 2B exemplifies the configuration of the constant current system whose off-circuit includes the switch 25 and the resistor 26. Similarly to the on-circuit, the off-circuit may be configured as the combination of a constant current source and a resistor.

The clamp circuit 3 temporarily clamps the gate voltage of the IGBT 1 to a clamp voltage when the IGBT 1 changes from the off-state to the on-state. The clamp circuit 3 according to the present embodiment can vary the clamp voltage in accordance with a mirror voltage variation. The clamp voltage used by the clamp circuit 3 for clamping is controlled based on a control-voltage control of the arithmetic device 5.

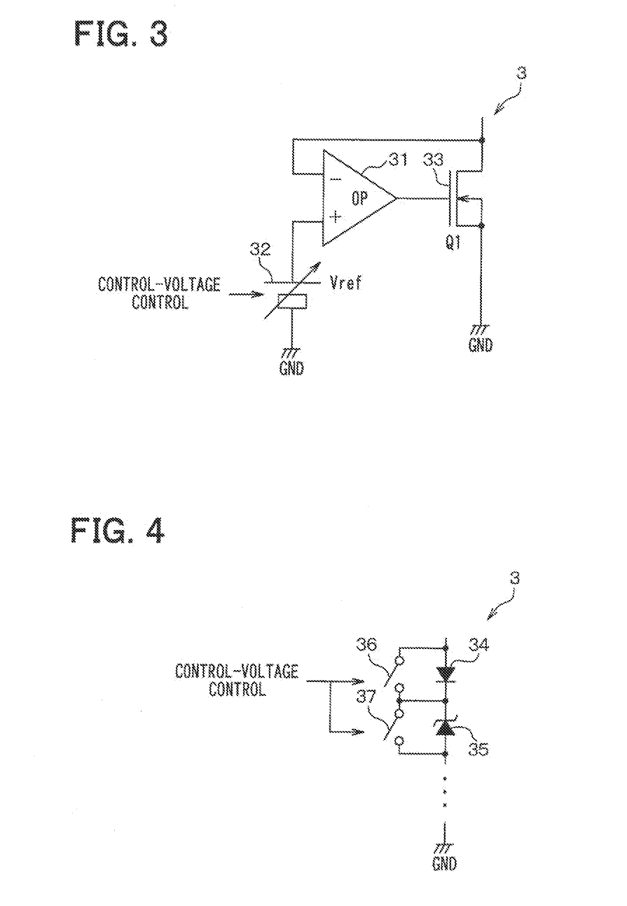

The clamp circuit 3 shown in FIG. 3 has only the current sink capability and includes an operational amplifier 31, a reference voltage circuit 32, and a MOSFET 33. As shown in FIG. 3, an inverting input terminal of the operational amplifier 31 is coupled between the gate of the IGBT 1 and the drain of the MOSFET. A non-inverting input terminal of the operational amplifier 31 is coupled to the reference voltage circuit 32. An output terminal of the operational amplifier 31 is coupled to the gate of the MOSFET 33.

When a reference voltage Vref generated from the reference voltage circuit 32 is adjusted by the control-voltage control of the arithmetic device 5, an output from the output terminal of the operational amplifier 31 is adjusted so that the gate voltage of the IGBT 1 approaches the reference voltage Vref, and current that flows from the MOSFET 33 is controlled. Specifically, when the gate voltage is lower than the reference voltage Vref, the MOSFET 33 is off. When the gate voltage reaches the reference voltage Vref, the MOSFET 33 starts operating based on an output signal from the operational amplifier 31. The output signal from the operational amplifier 31 is adjusted so that the gate voltage complies with the reference voltage Vref. Therefore, the gate voltage of the IGBT 1 can be clamped to the clamp voltage equivalent to the reference voltage Vref.

The temperature detection circuit 4 detects the temperature of the IGBT 1 based on temperature information from the temperature-sensitive diode 1a or an output potential between the above-mentioned temperature-sensitive diode 1a and the temperature detection resistor, for example. The temperature detection circuit 4 transmits a detection result to the arithmetic device 5.

The arithmetic device 5 adjusts the clamp voltage corresponding to the detection result from the temperature detection circuit 4 by calculating a control voltage for adjusting the clamp voltage of the clamp circuit 3 and performing the control-voltage control. The mirror voltage varies with the temperature of the IGBT 1. A mirror voltage variation can be estimated from the temperature of the IGBT 1. The clamp voltage is adjusted in accordance with the mirror voltage variation. Specifically, the mirror voltage is calculated based on the following equation (1).

Vmirror=Vth+√(Ic/gm). (1)

In the equation (1), Vmirror denotes the mirror voltage, Vth denotes a gate threshold voltage of the IGBT 1, gm denotes a current amplification factor, and Ic denotes an output current from the IGBT 1.

In the equation (1), the gate threshold voltage Vth and the current amplification factor gm vary with the temperature. The mirror voltage Vmirror also varies with the gate threshold voltage Vth and the current amplification factor gm dependent on the temperature. Accordingly, a variation in the mirror voltage Vmirror can be estimated based on the detected temperature of the IGBT 1. The control-voltage control is performed so that the clamp voltage is calculated in accordance with the variation in the mirror voltage Vmirror. The clamp voltage can be reduced to a value corresponding to the mirror voltage Vmirror at the detected temperature.

The above-mentioned configuration provides the load drive apparatus having a short circuit protection function according to the present embodiment.

The load drive apparatus according to the present embodiment calculates a clamp voltage each time the IGBT 1 is driven. The temperature detection circuit 4 detects the temperature of the IGBT 1 based on temperature information. Based on the detected temperature, the arithmetic device 5 calculates a clamp voltage corresponding to a variation in the mirror voltage Vmirror. The control-voltage control is performed so as to ensure the clamp voltage calculated by the arithmetic device 5. Accordingly, the clamp voltage adjusted by the clamp circuit 3 can be controlled at a low voltage corresponding to a variation in the mirror voltage Vmirror.

The temperature of the IGBT 1 is detected as described above. Then, based on the detected temperature, the clamp voltage is calculated in accordance with a variation in the mirror voltage Vmirror. Accordingly, the clamp voltage can be decreased to a value corresponding to the mirror voltage Vmirror at the detected temperature. The clamp voltage can be designed to be smaller than is designed in consideration of a maximum variation in the mirror voltage Vmirror, that is, in consideration of maximum values including all environmental changes. Therefore, the short circuit capacity can be improved while the IGBT 1 is restricted from increasing a loss during clamping.

The IGBT 1 is actually provided with a sense terminal, which is not shown in FIG. 1. A current flows through a main cell of the IGBT 1 via the sense terminal and is reduced at a predetermined rate to generate a sense current. Based on the sense current, the arithmetic device 5 detects a disconnection or overcurrent state. The disconnection state disables a current from flowing. The overcurrent state allows an excess current to flow. In addition, the arithmetic device 5 detects an overheated state of the IGBT 1 based on the temperature information from the temperature detection circuit 4. The IGBT 1 is heated at high temperature in the overheated state. If the disconnection, overcurrent, or overheated state is not detected, the arithmetic device 5 outputs an unclamp signal at a predetermined time and allows the clamp circuit 3 to unclamp the gate of the IGBT 1. The gate voltage of the IGBT 1 increases up to the full-on state. The IGBT 1 operates in a fully unsaturated state to supply a current to the load.

### Second Embodiment

A load drive apparatus according to a second embodiment of the present disclosure will be described. The present embodiment modifies the configuration of the clamp circuit 3 according to the first embodiment. The other features of the load drive apparatus according to the present embodiment are similar to the features of the load drive apparatus according to the first embodiment. Thus, only differences from the first embodiment will be described.

As shown in FIG. 4, the clamp circuit 3 according to the present embodiment also has only the current sink capability and includes a diode 34 that is coupled in a forward direction, a zener diode 35 that is coupled in a reverse direction, and switches 36 and 37 that are coupled in parallel with the diode 34 and the zener diode 35, respectively.

The control-voltage control of the arithmetic device 5 turns on or off the switches 36 and 37 to enable the clamp voltage regulated by a combination of the forward voltage Vf of the diode 34 and a zener breakdown voltage of the zener diode 35. For example, turning off the switch 36 and turning on the switch 37 enables the clamp voltage regulated by the forward voltage Vf of the diode 34. Turning on the switch 36 and turning off the switch 37 enables the clamp voltage regulated by the zener breakdown voltage of the zener diode 35. Turning off the switches 36 and 37 enables the clamp voltage regulated by a sum of the forward voltage Vf of the diode 34 and the zener breakdown voltage of the zener diode 35. The diode 34 and the zener diode 35 operate to clamp the gate voltage when the forward voltage Vf of the diode 34 or the zener voltage of the zener diode 35 is reached in accordance with selection of the switches 36 and 37. In order to disable the clamp, the switches 36, 37 are turned off and the clamp voltage is increased to be higher than an actual working voltage so as not to operate.

FIG. 4 shows one diode 34 and one zener diode 35. Further, multiple diodes 34 and multiple zener diodes 35 may be coupled. The clamp voltage may be regulated using the sum of forward voltages Vf of the diodes 34 or the sum of zener breakdown voltages of the zener diodes 35.

The diode 34, the zener diode 35, and the switches 36 and 37 may configure the clamp circuit 3 in this manner. The clamp circuit 3 having the above-described configuration can provide an effect similar to the first embodiment.

### Third Embodiment

A load drive apparatus according to a third embodiment of the present disclosure will be described. The present embodiment modifies the temperature detection technique according to the first embodiment. The other features of the load drive apparatus according to the present embodiment are similar to the features of the load drive apparatus according to the first embodiment. Thus, only differences from the first embodiment will be described.

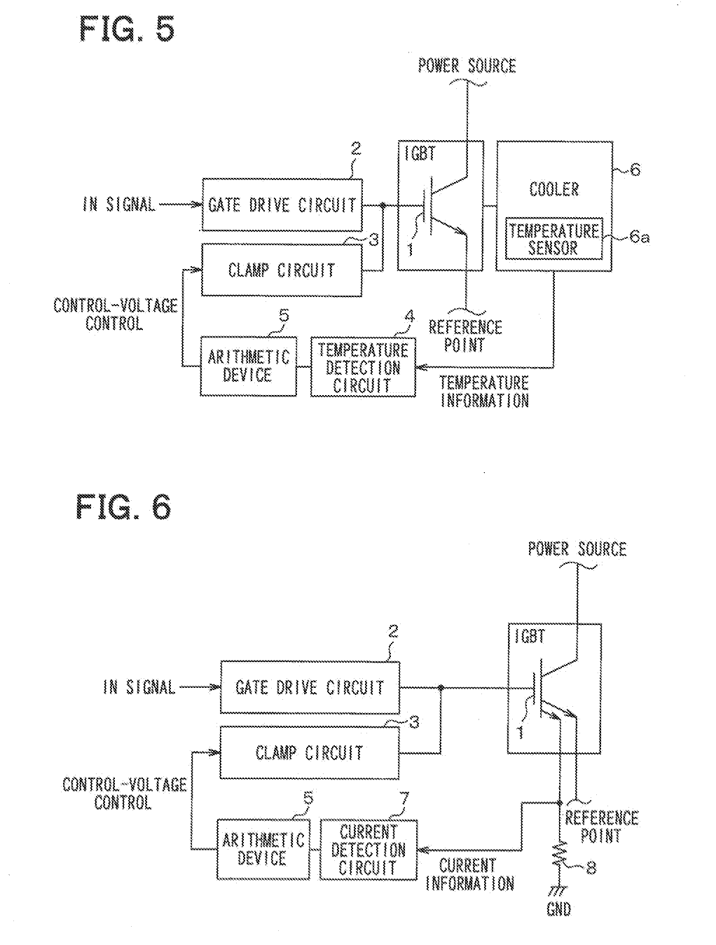

As shown in FIG. 5, a cooler 6 is provided for a heat-radiating switching device such as the IGBT 1 and releases heat from the IGBT 1 in order to prevent the IGBT 1 from overheating. The cooler 6 includes a temperature sensor 6a. A detection signal from the temperature sensor 6a may be used as temperature information for the temperature detection circuit 4 to detect the temperature of the IGBT 1. The temperature sensor 6a provided for the cooler 6 may indirectly detect the temperature of the IGBT 1. The cooler 6 may be provided as the water-cooling type or the air-cooling type. For the water-cooling type, the temperature sensor 6a may detect the water temperature. For the air-cooling type, the temperature sensor 6a may detect the air temperature. That is, the temperature sensor 6a may detect the temperature of a cooling medium used for cooling.

### Fourth Embodiment

A load drive apparatus according to a fourth embodiment of the present disclosure will be described. The load drive apparatus according to the present embodiment detects an output current from the IGBT 1 and thereby calculates a variation in the mirror voltage Vmirror instead of the temperature detection according to the first embodiment. The other features of the load drive apparatus according to the present embodiment are similar to the features of the load drive apparatus according to the first embodiment. Thus, only differences from the first embodiment will be described.

As shown in FIG. 6, the IGBT 1 includes a main cell and a sense cell. In the main cell, an output current for current supply to the load flows. In the sense cell, a sense current that is generated from the output current flowing through the main cell by reducing the output current at a predetermined rate flows. As shown in FIG. 6, a current detection circuit 7 is provided to detect a current based on the sense current flowing from the sense terminal. Specifically, the current detection circuit 7 is supplied with current information, that is, a potential between the sense terminal and a sense resistor 8 coupled to the sense terminal, thereby detecting an output current flowing through the main cell of the IGBT 1.

As expressed in the equation (1), the mirror voltage Vmirror depends on an output current Ic from the IGBT 1 as well as the temperature of the IGBT 1. Detecting the output from the IGBT 1 enables to settle a clamp voltage corresponding to a variation in the mirror voltage Vmirror for the output current and keep the clamp voltage low. Therefore, detecting the output from the IGBT 1 can also provide the effect according to the first embodiment.

### Fifth Embodiment

A load drive apparatus according to the fifth embodiment of the present disclosure will be described. The load drive apparatus according to the present embodiment also calculates a variation in the mirror voltage Vmirror by detecting an output current from the IGBT 1 as described in the fourth embodiment.

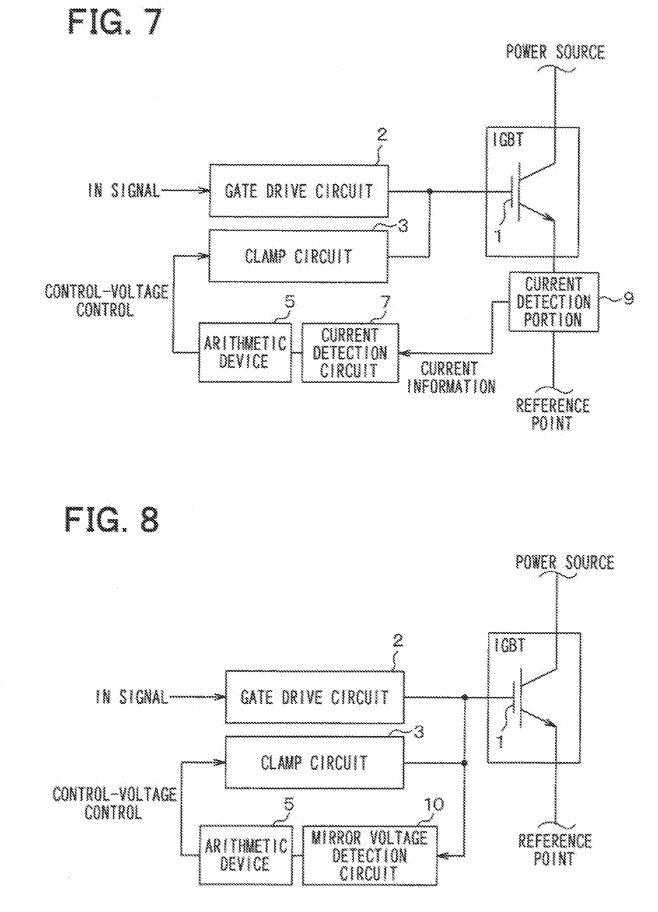

As shown in FIG. 7, a current detection portion 9 is provided to generate current information, that is, an output corresponding to the output current from the IGBT 1. The current detection circuit 7 is supplied with an output from the current detection portion 9 as temperature information. Accordingly, the current detection circuit 7 detects an output current flowing through the main cell of the IGBT 1. A Hall device may be used as the current detection portion 9, for example. The output current flows through a current supply line coupled to the emitter or the collector of the IGBT 1 and generates a magnetic field. The Hall device converts the generated magnetic field into an electric signal and outputs the electric signal.

The current detection portion 9 can directly detect the output current from the IGBT 1. Like the fourth embodiment, the fifth embodiment can provide the effect described in the first embodiment.

### Sixth Embodiment

A load drive apparatus according to a sixth embodiment of the present disclosure will be described. The load drive apparatus according to the present embodiment detects the mirror voltage Vmirror and thereby calculating a variation in the mirror voltage Vmirror instead of the temperature detection according to the first embodiment or the detection of an output current from the IGBT 1 according to the fourth embodiment. The other features of the load drive apparatus according to the present embodiment are similar to the features of the load drive apparatus according to the first embodiment. Thus, only differences from the first embodiment will be described.

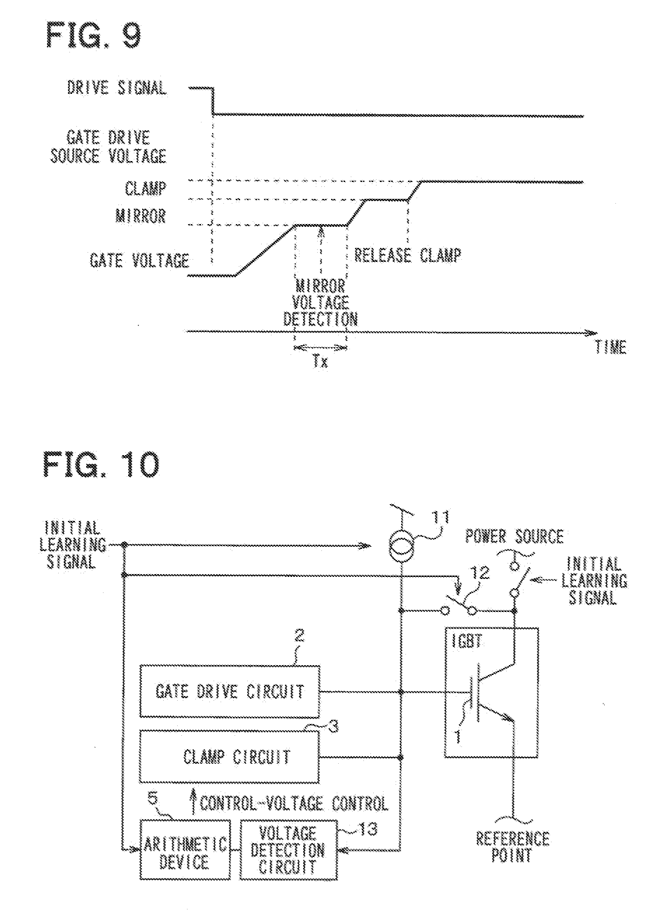

As shown in FIG. 8, a mirror voltage detection portion 10 is provided to detect the gate voltage of the IGBT 1. The mirror voltage detection portion 10 directly detects the gate voltage as the mirror voltage. For example, the mirror voltage detection portion 10 always detects the gate voltage of the IGBT 1. The mirror voltage detection portion 10 notifies the arithmetic device 5 of a value corresponding to the gate voltage, and the arithmetic device 5 holds the value. The arithmetic device 5 holds the value of the mirror voltage Vmirror that takes effect during period Tx shown in FIG. 9. The arithmetic device 5 calculates the clamp voltage corresponding to the mirror voltage Vmirror. The control-voltage control finally adjusts the clamp voltage.

The mirror voltage Vmirror can be directly detected in the above-described manner. Accordingly, the load drive apparatus according to the present embodiment can also provide the effect described in the first embodiment.

In addition, the mirror voltage Vmirror may be detected as follows.

The mirror voltage takes effect during a mirror period. Normally, the mirror period is short in order to decrease a switching loss. The gate voltage can be detected at the time to start the mirror period after elapse of a predetermined time following the IN signal. The gate voltage can be detected as the mirror voltage Vmirror. The gate voltage increases in accordance with the gate capacity of the IGBT 1 based on a predetermined procedure. The mirror voltage Vmirror may be assumed to take effect after elapse of a predetermined time since the gate voltage exceeds a threshold value. The gate voltage may be detected at the time and may be assumed to be the mirror voltage Vmirror.

### Seventh Embodiment

A load drive apparatus according to a seventh embodiment of the present disclosure will be described. The load drive apparatus according to the first to sixth embodiments detect a variation in the mirror voltage Vmirror due to an environmental change of the IGBT 1. On the other hand, the load drive apparatus according to the present embodiment initially learns the gate threshold voltage Vth for the IGBT 1 at startup and learns a variation in the mirror voltage Vmirror due to a variation in the gate threshold voltage Vth resulting from a manufacturing variation of the IGBT 1.

As shown in FIG. 10, the load drive apparatus includes a constant current source 11, a switch 12, and a voltage detection circuit 13. The constant current source 11 supplies a constant current to the gate and the collector of the IGBT 1. The switch 12 turns on or off the constant current supply to the collector. The voltage detection circuit 13 detects the gate threshold voltage Vth. To perform initial learning according to this configuration, an initial learning signal turns on the switch 12 to short-circuit between the gate and the collector. In addition, the initial learning signal allows the constant current source 11 to generate a constant current. As a result, the constant current can drive the IGBT 1. The gate threshold voltage Vth for the IGBT 1 can be detected while the voltage detection circuit 13 detects a voltage between the gate and the emitter or a voltage between the collector and the emitter.

The initial learning signal is supplied to the arithmetic device 5 so that the arithmetic device 5 is notified of the initial learning condition. The arithmetic device 5 finds a variation in the gate threshold voltage Vth from the gate threshold voltage Vth detected in the voltage detection circuit 13 and learns (stores) the variation. The arithmetic device 5 uses the variation in the gate threshold voltage Vth to calculate the mirror voltage Vmirror based on the above-described equation (1). The arithmetic device 5 calculates a clamp voltage corresponding to the calculated mirror voltage Vmirror. The variation in the gate threshold voltage Vth the arithmetic device 5 learns may be equivalent to a variation in the mirror voltage Vmirror or a control quantity of the clamp voltage or the control-voltage control (the reference voltage Vref for the reference voltage circuit 32 shown in FIG. 3 or the on-off state of the switches 36 and 17 shown in FIG. 4). The arithmetic device 5 settles a clamp voltage based on the learning result when the IGBT 1 is driven to supply current to the load.

The arithmetic device 5 can initially learn the gate threshold voltage Vth and can settle a clamp voltage based on the learning result. Therefore, the load drive apparatus according to the present embodiment provides an effect similar to the first embodiment. The similar effect is also available if the arithmetic device 5 varies a constant current value at the initial learning, measures a voltage between the gate and the emitter at the time as well as the gate threshold voltage Vth, and calculates the current amplification factor gm.

The initial learning is assumed to be performed before the IGBT 1 is driven. In addition to this case, the arithmetic device 5 may once learn the gate threshold voltage Vth at the time of modularizing semiconductor devices, that is, during a manufacturing stage of semiconductor devices and may store the learning result in a memory and the like.

The above-described first to seventh embodiments use the IGBT 1 as an example of switching devices. The switching devices may further include semiconductor switching devices such as power MOSFETs as well as the IGBT 1. In this case, the learning according to the seventh embodiment just needs to detect a voltage between the gate and the source. In other words, a first electrode (collector electrode or drain electrode) of the switching device is coupled to the power supply side of the current supply line to the load and a second electrode (emitter electrode or source electrode) of the switching device is coupled to the reference point side. The switching device controls the on-off state of the current supply line by controlling the gate voltage. The leaning can be performed by detecting the voltage between the gate and the second electrode.

The gate drive circuit 2 and the clamp circuit 3 are provided as circuit examples. Other circuit configurations may be also available if the circuit configurations ensure similar operations. In the load drive apparatus according to the seventh embodiment, the constant current source 11 is disposed at the collector side of the IGBT 1. The constant current source 11 may also be disposed at the emitter side.

### Eighth Embodiment

A semiconductor switching device drive apparatus according to an eighth embodiment of the present disclosure will be described. The semiconductor switching device drive apparatus according to the present embodiment uses a constant current to drive semiconductor switching devices such as an IGBT and a power MOSFET.

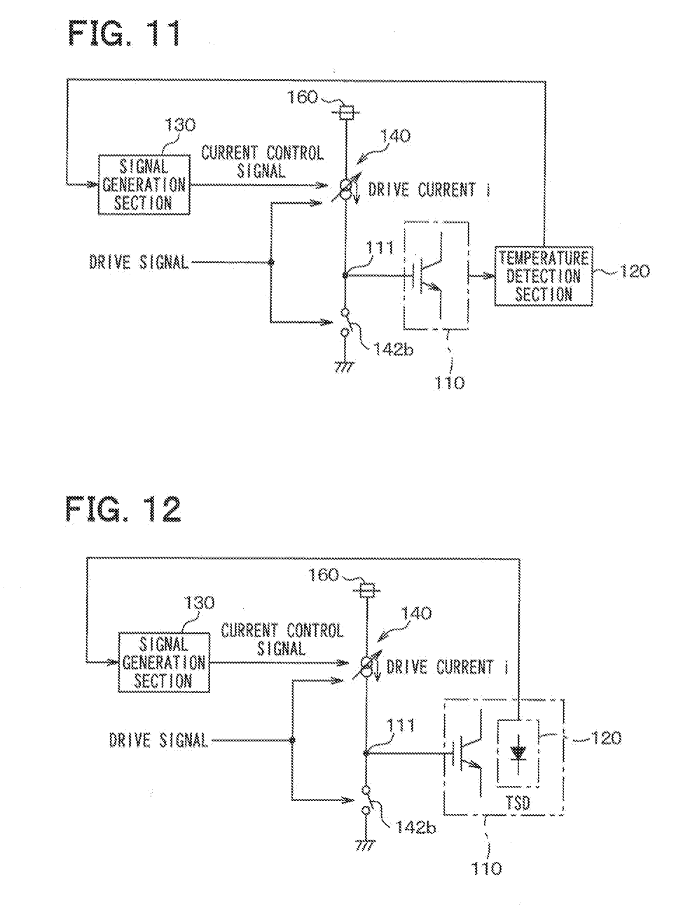

As shown in FIG. 11, the semiconductor switching device drive apparatus includes a semiconductor switching device 110, a temperature detection section 120, a signal generation section 130, and a drive section 140.

The semiconductor switching device 110 drives a load (not shown). In the present embodiment, an N channel-type IGBT is employed as the semiconductor switching device 110. The semiconductor switching device 110 includes a control terminal 111 as the gate. The control terminal 111 is coupled to the drive section 140. The load (not shown) is coupled to the source side or the drain side of the semiconductor switching device 110. A drive current i is applied to the control terminal 111, thereby driving the semiconductor switching device 110.

The temperature detection section 120 detects a device temperature of the semiconductor switching device 110 or the ambient temperature of the semiconductor switching device 110. As shown in FIG. 12, in the present embodiment, a temperature-sensitive device (TSD) included in the semiconductor switching device 110 is employed as the temperature detection section 120. A power device such as an IGBT can be provided with a temperature-sensitive device that detects an operating temperature of the device. The temperature-sensitive device includes a diode formed on an insulation layer of the IGBT, for example. In a case where the temperature detection section 120 includes the temperature-sensitive device, when the operating temperature of the IGBT includes, an output (forward voltage) from the diode decreases.

The temperature detection section 120 outputs a voltage corresponding to the temperature as a detection result (temperature information Va) to the signal generation section 130. In the present embodiment, when the temperature of the semiconductor switching device 110 increase, the value of the temperature information Va also increases.

The signal generation section 130 receives the detection result from the temperature detection section 120. Based on the detection result, the signal generation section 130 generates and outputs a current control signal that changes a drive current applied to the control terminal 111 of the semiconductor switching device 110.

The drive section 140 generates drive current i applied to the control terminal 111 of the semiconductor switching device 110 and applies the drive current i to the control terminal 111 to drive the semiconductor switching device 110. A capability or a switching speed of the drive section 140 depends on the drive current i. On-time is required until the semiconductor switching device 110 turns on. Increasing the drive current shortens the on-time. Shortening the on-time increases the switching speed.

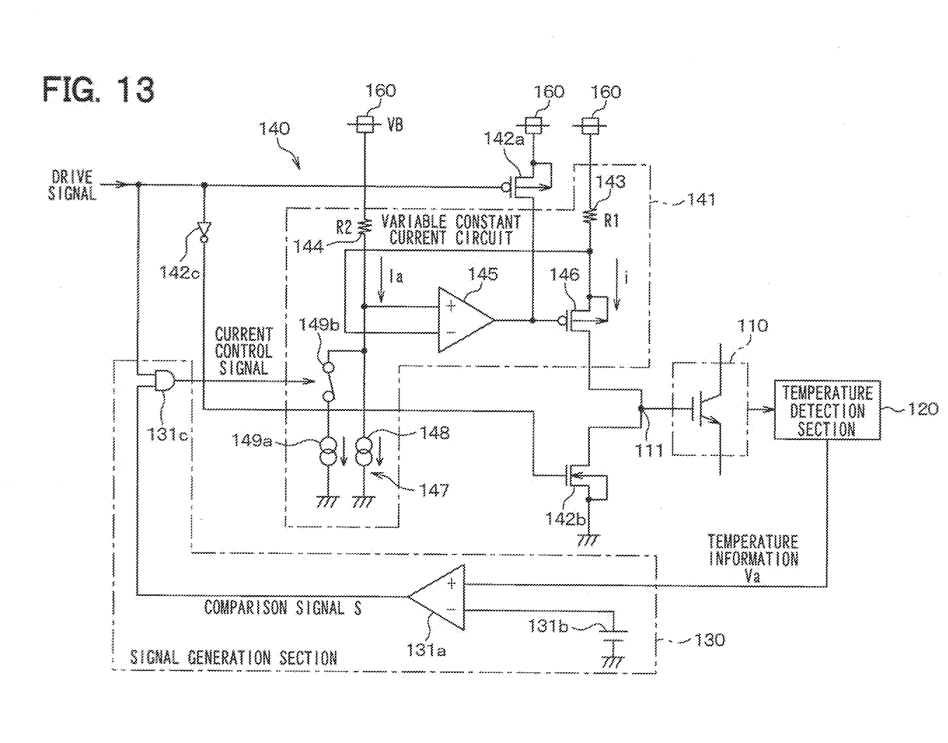

The overview of the semiconductor switching device drive apparatus has been described. The following describes a specific circuit configuration of the semiconductor switching device drive apparatus with reference to FIG. 13.

As shown in FIG. 12, the temperature detection section 120 is configured as a temperature-sensitive device and is included in the semiconductor switching device 110.

The signal generation section 130 includes a comparator 131a, a reference voltage source 131b, and an AND circuit 131c. The comparator 131a compares the detection result (temperature information Va) from the temperature detection section 120 with a temperature threshold set for the detection result and outputs a comparison result as a comparison signal S. The reference voltage source 131b generates a reference voltage used as the temperature threshold. A non-inverting input terminal (+) of the comparator 131a is supplied with a voltage corresponding to the temperature from the temperature detection section 120. An inverting input terminal (−) of the comparator 131a is supplied with the reference voltage as the temperature threshold. The comparator 131a outputs a high-level comparison signal if Va exceeds the temperature threshold. The comparator 131a outputs a low-level comparison signal if Va is smaller than the temperature threshold.

The AND circuit 131c outputs a high-level current control signal if both of the drive signal and the comparison signal are high. The AND circuit 131c outputs a low-level current control signal if one of the drive signal and the comparison signal is low.

The drive section 140 includes a variable constant current circuit 141, a first changeover switch 142a, and a second changeover switch 142b. The variable constant current circuit 141 includes a first resistor 143 (R1 in FIG. 13), a second resistor 144 (R2 in FIG. 13), an operational amplifier 145, a switching device 146, and a constant current source 147.

The first resistor 143 is used for sensing and is supplied with a current corresponding to the drive current i flowing to the control terminal 111 of the semiconductor switching device 110. One end of the first resistor 143 is coupled to a power source 160 (VB in FIG. 13) and the other end of the first resistor 143 is coupled to the switching device 146. One end of the second resistor 144 is coupled to the power source 160 and the other end of the second resistor 144 is coupled to the constant current source 147.

The operational amplifier 145 feedback-controls a current flowing to the first resistor 143 based on a voltage at the other end of the second resistor 144, thereby adjusting the magnitude of the drive current i supplied to the control terminal 111 of the semiconductor switching device 110.

A non-inverting input terminal (+) of the operational amplifier 145 is coupled to a connection point between the other end of the second resistor 144 and the constant current source 147. As a result, the non-inverting input terminal of the operational amplifier 145 is supplied with a first voltage corresponding to the other end of the second resistor 144. When VB denotes the voltage of the power source 160, Ia denotes the current flowing to the second resistor 144, and R2 denotes the resistance value of the second resistor 144, the first voltage corresponds to a voltage (VB−Ia×R2) obtained by subtracting the reference voltage from the power supply voltage.

An inverting input terminal (−) of the operational amplifier 145 is coupled to the other end of the first resistor 143. As a result, the inverting input terminal of the operational amplifier 145 is supplied with a second voltage corresponding to the other end of the first resistor 143. When i denotes the current flowing to the first resistor 143, and R1 denotes the resistance value of the first resistor 143, the second voltage corresponds to a voltage (VB−i×R1) obtained by subtracting a voltage drop in the first resistor 143 from the power supply voltage.

The switching device 146 is a semiconductor device that is driven by output from the operational amplifier 145. In the present embodiment, a P channel-type MOSFET is employed as the switching device 146. The gate of the switching device 146 is coupled to an output terminal of the operational amplifier 145 and the source of the switching device 146 is coupled to the other end of the first resistor 143. The drain of the switching device 146 is coupled to the control terminal 111 of the semiconductor switching device 110.

The constant current source 147 is capable of varying the amount of a reference current Ia flowing to the second resistor 144 and is coupled between the other end of the second resistor 144 and the ground. The constant current source 147 includes a first constant current source 148, a second constant current source 149a, and a switch 149b.

The second constant current source 149a is coupled to the other end of the second resistor 144 via the switch 149b. The first constant current source 148 is directly coupled to the other end of the second resistor 144. The switch 149b turns on or off in accordance with a current control signal supplied from the signal generation section 130. In the present embodiment, a high-level current control signal turns on the switch 149b and a low-level current control signal turns off the switch 149b.

The first constant current source 148 and the second constant current source 149a may or may not have the same current capability. The constant current sources 148 and 149a may be provided with current capabilities in accordance with the design that specifies the magnitude of a current supplied to the second resistor 144 when the switch 149b is turned on or off.

When the current control signal turns on the switch 149b, a current of a first current value flows in the second resistor 144. The first current value is the sum of the current flowing to the second constant current source 149a and the current flowing to the first constant current source 148. On the other hand, the current flowing to the second constant current source 149a is decoupled from the path between the power source 160 and the ground when the current control signal turns off the switch 149b. Thus, only the current supplied to the first constant current source 148 flows in the second resistor 144. The second current value is assigned to the current flowing to the first constant current source 148. When the switch 149b is turned off, the current of the second current value smaller than the first current value flows in the second resistor 144. In other words, the constant current source 147 supplies the current of the first current value if the detection result from the temperature detection section 120 indicates high temperature over the temperature threshold. On the other hand, the constant current source 147 supplies the current of the second current value smaller than the first current value if the detection result from the temperature detection section 120 indicates a temperature below the temperature threshold. There has been described the configuration of the variable constant current circuit 141.

The first changeover switch 142a and the second changeover switch 142b control the on-off state of the semiconductor switching device 110 by “allowing” or “disallowing” the drive section 140 to supply the drive current i to the control terminal 111 in accordance with the drive signal. In the present embodiment, the “allowance” corresponds to turning off the first changeover switch 142a and the second changeover switch 142b. The “disallowance” corresponds to turning on the first changeover switch 142a and the second changeover switch 142b.

The first changeover switch 142a is coupled between the power source 160 and the output terminal of the operational amplifier 145. In the present embodiment, a P channel-type MOSFET is employed as the first changeover switch 142a. The source of the first changeover switch 142a is coupled to the power source 160 and the drain of the first changeover switch 142a is coupled to the output terminal of the operational amplifier 145.

The second changeover switch 142b is coupled between the control terminal 111 and the ground. In the present embodiment, an N channel-type MOSFET is employed as the second changeover switch 142b. The source of the second changeover switch 142b is coupled to the control terminal 111 of the semiconductor switching device 110 and the drain of the second changeover switch 142b is coupled to the ground.

An inverter 142c is coupled to the gate of the second changeover switch 142b. The drive signal is input to the second changeover switch 142b via the inverter 142c. The drive signal is directly input to the first changeover switch 142a. The signal input to one of the switches 142a and 142b is inverted when input to the other. FIG. 11 and FIG. 12 show only the second changeover switch 142b.

In the present embodiment, the drive signal is input from an external ECU, for example. In the present embodiment, the high-level drive signal turns on the semiconductor switching device 110.

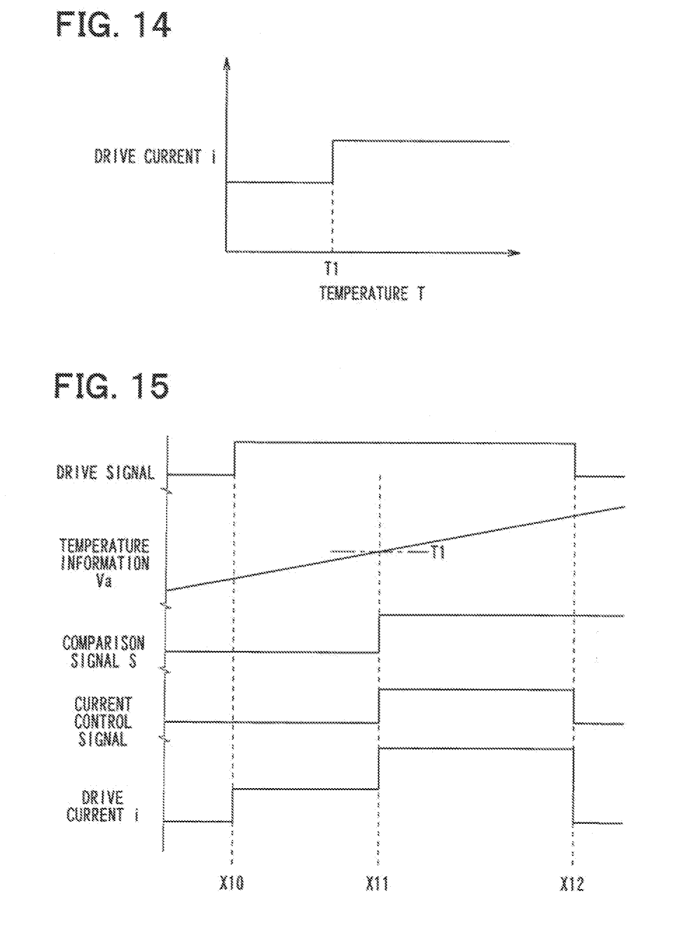

With reference to FIG. 14 and FIG. 15, the following describes operations of the semiconductor switching device drive apparatus shown in FIG. 11 to FIG. 13. In the following description, the device temperature or the ambient temperature detected by the temperature detection section 120 is called, simply, the temperature of the semiconductor switching device 110.

In the above-mentioned configurations, the drive section 140 changes the magnitude of the drive current i applied to the control terminal 111 in accordance with the temperature of the semiconductor switching device 110 while the temperature detection section 120 detects the temperature. Specifically, increasing the temperature of the semiconductor switching device 110 increases the drive current i. The reason follows. A surge easily occurs at a low temperature and the drive current i is decreased to suppress occurrence and variation of the surge. A surge hardly occurs at a high temperature and the drive current i is increased to increase the switching speed.

In FIG. 14, “T1” denotes the above-mentioned temperature threshold. The drive current i increases stepwise if the temperature of the semiconductor switching device 110 exceeds the temperature threshold T1. The magnitude of the drive current i corresponds to the second current value of the constant current source 147 if the temperature is lower than or equal to the temperature threshold T1. The magnitude of the drive current i corresponds to the first current value of the constant current source 147 if the temperature is higher than or equal to the temperature threshold T1.

The timing diagram shown in FIG. 15 will be described. At time point X10, the drive signal supplied to the drive section 140 changes from the low level to the high level to turn off the first changeover switch 142a and the second changeover switch 142b. The operational amplifier 145 drives the switching device 146. The drive current i flows to the control terminal 111 of the semiconductor switching device 110.

The variable constant current circuit 141 feedback-controls the magnitude of the current flowing to the first resistor 143 so that the first voltage corresponding to the other end of the first resistor 143 equals to the second voltage corresponding to the other end of the second resistor 144.

The same potential is maintained at the input terminals of the operational amplifier 145 in the variable constant current circuit 141. Specifically, the operational amplifier 145 controls the switching device 146 so that the first voltage (VB−i×R1) corresponding to the other end of the first resistor 143 equals to the second voltage (VB−Ia×R2) corresponding to the other end of the second resistor 144. The drive current i flowing to the first resistor 143 is expressed as i=(Ia×R2)/R1. The reference current Ia flowing to the first resistor 143 is applied as the constant drive current i to the control terminal 111 of the semiconductor switching device 110. In other words, as expressed as i=(Ia×R2)/R1, the current proportional to the magnitude of the reference current Ia flowing to the second resistor 144 flows in the first resistor 143 toward the control terminal 111.

In other words, the operational amplifier 145 compares the drive current i applied to the control terminal 111 with the reference current Ia. The operational amplifier 145 varies the drive current i applied to the control terminal 111 by varying an output corresponding to the reference current Ia that varies with the current control signal.

After time point X10, the temperature information Va is lower than the temperature threshold T1. The comparator 131a of the signal generation section 130 outputs a low-level comparison signal S. The AND circuit 131c also outputs the low-level current control signal. The switch 149b of the constant current source 147 is turned off. Therefore, the second resistor 144 allows only a current of the second current value smaller than the first current value. This current flows as the reference current Ia to the first constant current source 148.

At time point X11, the temperature information Va exceeds the temperature threshold T1. The comparator 131a of the signal generation section 130 outputs the high-level comparison signal S. The AND circuit 131c also outputs the high-level current control signal. The switch 149b of the constant current source 147 is turned on. Therefore, the current of the first current value in flows in the second resistor 144 as the reference current Ia that corresponds to the sum of the current flowing to the second constant current source 149a and the current flowing to the first constant current source 148. In the first resistor 143, the current proportional to the first current value flows. As a result, the drive current i increases at time point X11 as shown in FIG. 15. In this manner, the drive section 140 varies the drive current applied to the control terminal 111 based on the comparison result from the comparator 131a. The drive current i can be increased at the high temperature that hardly causes a surge. The semiconductor switching device 110 can increase the slew rate, thereby increasing the switching speed.

At the subsequent time point X12, the drive signal input to the drive section 140 changes from the high level to the low level. An instruction to turn off the semiconductor switching device 110 turns on the first changeover switch 142a and the second changeover switch 142b and turns off the switching device 146. An electric charge stored in the control terminal 111 is discharged to the ground via the second changeover switch 142b. The gate voltage at the control terminal 111 becomes lower than the threshold voltage and turns off the semiconductor switching device 110.

As described above, the drive current i increases if the temperature of the semiconductor switching device 110 becomes high during a period in which the semiconductor switching device 110 remains on. Though not shown in the timing diagram, if the temperature information Va becomes lower than the temperature threshold T1, the reference current Ia decreases and the drive current i also decreases stepwise.

As described above, in the present embodiment, the drive current i applied to the control terminal 111 varies in accordance with the temperature of the semiconductor switching device 110. The drive current can be decreased to decrease the slew rate at a low temperature at which a surge is more likely to be caused. Thus, occurrence and variation of a surge voltage due to a temperature change in the semiconductor switching device 110 can be restricted. On the other hand, the drive current can be increased to increase the slew rate at a high temperature at which a surge is less likely to be caused. Accordingly, the switching speed of the semiconductor switching device 110 increases. As a result, a switching loss can be reduced. Thus, occurrence and variation of a surge voltage due to a temperature change in the semiconductor switching device 110 can be restricted and a switching loss can be decreased.

In the present embodiment, the comparator 131a can operate as a temperature comparison section, the constant current source 147 can operate as a current source, the operational amplifier 145 can operate as a current comparison section, and the first changeover switch 142a, the second changeover switch 142b, and the inverter 142c can operate as a control section.

### Ninth Embodiment

A semiconductor switching device drive apparatus according to a ninth embodiment of the present disclosure will be described. The semiconductor switching device drive apparatus according to the present embodiment adjusts a resistance value of the second resistor 144, thereby adjusting the quantity of the drive current i applied to the control terminal 111 of the semiconductor switching device 110.

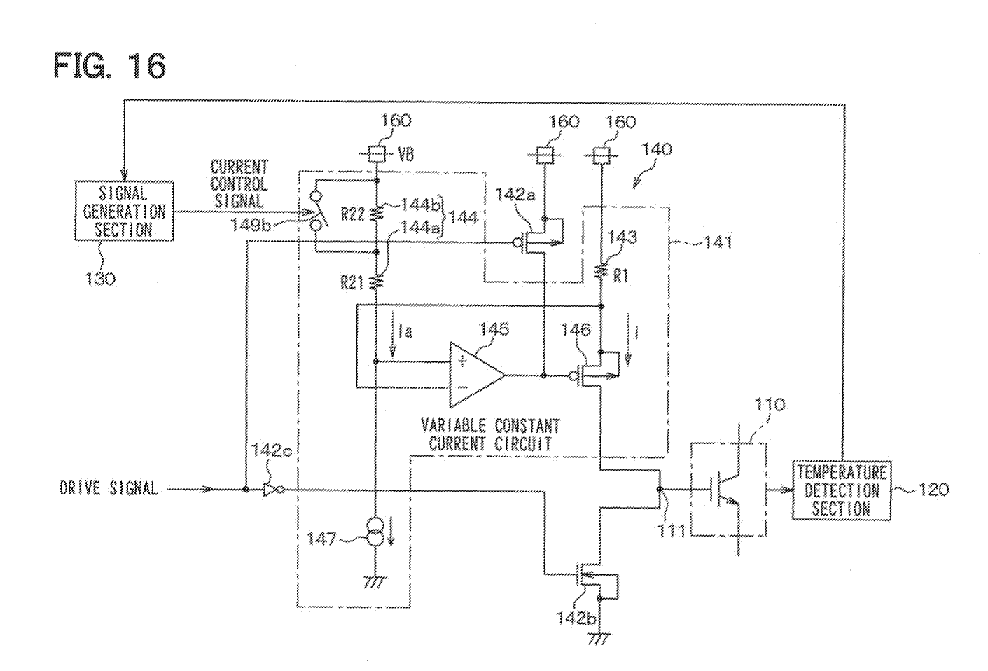

As shown in FIG. 16, the variable constant current circuit 141 is provided with the second resistor 144 that includes a resistor 144a (R21 in FIG. 16) and a resistor 144b (R22 in FIG. 16) coupled to each other in series. One end of the resistor 144b is coupled to the power source 160 and the other end of the resistor 144b is coupled to one end of the resistor 144a. The other end of the resistor 144a is coupled to the non-inverting input terminal (+) of the operational amplifier 145.

The resistor 144b of the second resistor 144 is coupled in parallel with a switch 149b that is turned on or off in accordance with a current control signal output from the signal generation section 130. When the switch 149b is turned on, a resistance value of the second resistor 144 becomes a resistance value of the resistor 144a. When the switch 149b is turned off, the resistance value of the second resistor 144 becomes the sum of resistance values of the resistors 144a and 144b.

The configuration of the signal generation section 130 is similar to the configuration of the signal generation section 130 described in the eighth embodiment. However, in the present embodiment, a low-level current control signal turns on the switch 149b and a high-level current control signal turns off the switch 149b.

The drive section 140 includes the constant current source 147 that supplies a predetermined reference current Ia. The operational amplifier 145 according to the present embodiment compares the drive current i applied to the control terminal 111 with the reference current Ia or outputs a difference between these currents. The resistance value of the second resistor 144 varies in accordance with the current control signal to vary an output from the operational amplifier 145 and accordingly the drive current applied to the control terminal 111 varies. That is, the operational amplifier 145 is supplied with the first voltage corresponding to the other end of the first resistor 143 and the second voltage corresponding to the other end of the second resistor 144 or the other end of the resistor 144a. In addition, the operational amplifier 145 drives the switching device 146 so that the first voltage equals to the second voltage.

The low-level current control signal turns on the switch 149b if the signal generation section 130 determines that the temperature information Va is below the temperature threshold T1. As a result, the reference current Ia flows to the resistor 144a only. When the resistor 144a has resistance value R21, the drive current i flowing to the first resistor 143 is expressed as i=(Ia×R21)/R1 as described above. In the first resistor 143 a current proportional to the resistance value R21 of the resistor 144a flows.

On the other hand, the high-level current control signal turns off the switch 149b if the signal generation section 130 determines that the temperature information Va exceeds the temperature threshold T1. As a result, the reference current Ia flows to both the resistors 144a and 144b. When the resistor 144b has resistance value R22, the drive current i flowing to the first resistor 143 is expressed as i=(Ia×(R21+R22))/R1. In the first resistor 143, a current proportional to the sum of the resistance value R21 of the resistor 144a and the resistance value R22 of the resistor 144b flows.

In accordance with the current control signal, that is, when the switch 149b is turned off, the drive section 140 increases the resistance value of the second resistor 144 to which the reference current Ia flows. Accordingly, the drive section 140 varies an output from the operational amplifier 145 and can increase the drive current i applied to the control terminal 111.

As described above, adjusting the resistance value of the second resistor 144 can increase or decrease the drive current i applied to the control terminal 111 of the semiconductor switching device 110.

In the present embodiment, the second resistor 144 can operate as a variable resistor, and the operational amplifier 145 can operate as an output section.

### Tenth Embodiment

A semiconductor switching device drive apparatus according to a tenth embodiment of the present disclosure will be described. The semiconductor switching device drive apparatus according to the present embodiment varies a resistance value of the first resistor 143 to vary the drive current i.

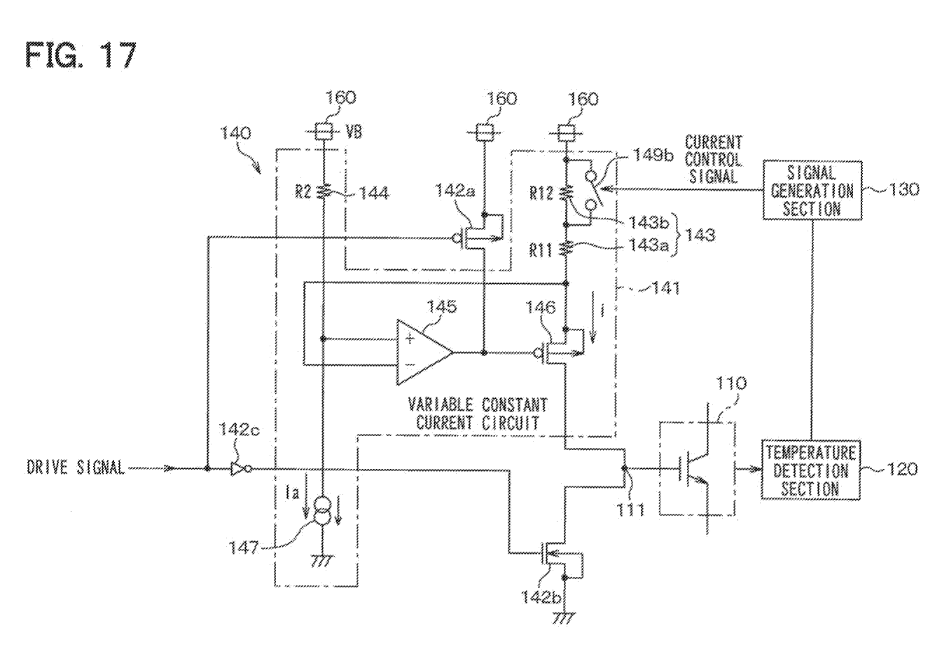

As shown in FIG. 17, the variable constant current circuit 141 is provided with the first resistor 143 that includes a resistor 143a (R11 in FIG. 17) and a resistor 143b (R12 in FIG. 17) coupled to each other in series. One end of the resistor 143b is coupled to the power source 160 and the other end of the resistor 143b is coupled to one end of the resistor 143a. The other end of the resistor 143a is coupled to the switching device 146.

In the first resistor 143, the resistor 143b coupled in parallel with the switch 149b that is turned on or off in accordance with a current control signal output from the signal generation section 130. When the switch 149b is turned on, the resistance value of the first resistor 143 becomes a resistance value of the resistor 143a. When the switch 149b is turned off, the resistance value of the first resistor 143 becomes the sum of resistance values of the resistors 143a and 143b. In the present embodiment, a low-level current control signal turns on the switch 149b and a high-level current control signal turns off the switch 149b.

The configuration of the signal generation section 130 is similar to the configuration of the signal generation section 130 described in the eighth embodiment. Similarly to the ninth embodiment, the drive section 140 includes the constant current source 147 that supplies the predetermined reference current Ia.

In the embodiment, a low-level current control signal turns off the switch 149b if the signal generation section 130 determines that the temperature information Va is lower than the temperature threshold T1. As a result, both resistors 143a and 143b configure the first resistor 143. When the resistor 143a has resistance value R11 and the resistor 143b has resistance value R12, the drive current i flowing to the first resistor 143 is expressed as i=(Ia×(R2))/(R11+R12). In the first resistor 143, the drive current i inversely proportional to the sum of the resistance value R11 of the resistor 143a and the resistance value R12 of the resistor 144b flows. The drive current i is small because the denominator is large.

On the other hand, the high-level current control signal turns on the switch 149b if the signal generation section 130 determines that the temperature information Va exceeds the temperature threshold T1. As a result, only the resistor 143a configures the first resistor 143. The drive current i flowing to the first resistor 143 is expressed as i=(Ia×R2)/R11. In the first resistor 143, a current proportional to the resistance value R11 for the resistor 143a flows. The drive current i is large because the denominator is small.

As described above, the drive section 140 can vary the magnitude of the drive current i applied to the control terminal 111 by varying the resistance value of the first resistor 143 in accordance with the current control signal.

In the present embodiment, the first resistor 143 can operate as a variable resistor.

### Eleventh Embodiment

A semiconductor switching device drive apparatus according to an eleventh embodiment of the present disclosure will be described. The semiconductor switching device drive apparatus according to the present embodiment varies the drive current I in a stepwise manner based on multiple temperature thresholds.

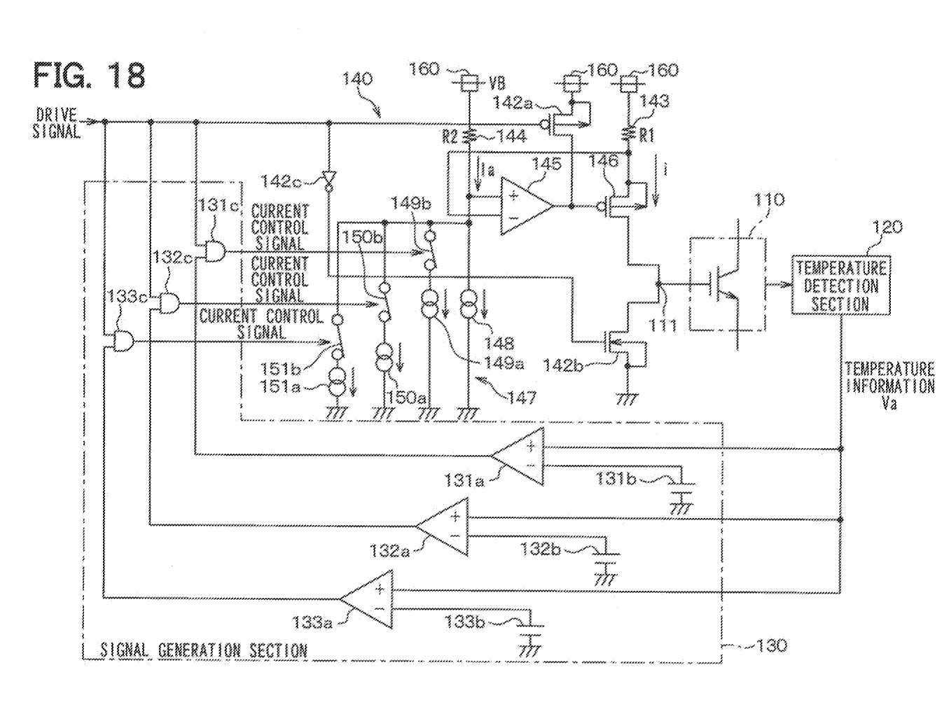

As shown in FIG. 18, the signal generation section 130 includes three comparators 131a to 133a, reference voltage sources 131b to 133b, and AND circuits 131c to 133c corresponding to the comparators 131a to 133a. The reference voltage source 131b is provided with a reference voltage as the temperature threshold T1. The reference voltage source 132b is provided with a reference voltage as a temperature threshold T2. The reference voltage source 133b is provided with a reference voltage as a temperature threshold T3. In the present embodiment, the temperature thresholds T1-T3 satisfies a relationship of T1<T2<T3. Each of the AND circuits 131c to 133c outputs a current control signal.

The constant current source 147 in the drive section 140 includes second to fourth constant current sources 149a to 151a corresponding to the AND circuits 131c to 133c. Switches 149b to 151b are coupled to the constant current sources 149a to 151a. The constant current sources 149a to 151a may or may not have the same current capability.

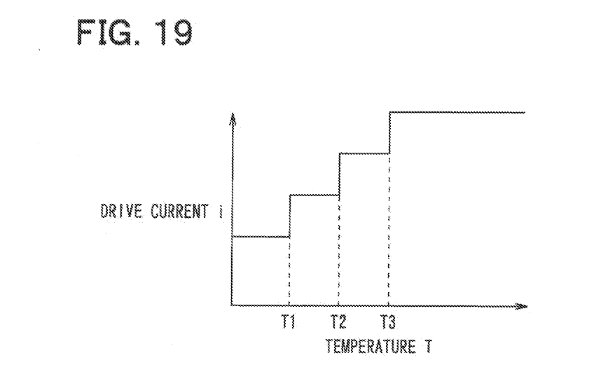

FIG. 19 shows the relationship between the temperature and the drive current i of the semiconductor switching device. If the temperature information Va is lower than the temperature threshold T1, all switches 149b to 151b are off. Only a current from the second constant current source 149a is used as the reference current Ia. Therefore, the drive current i flows based on i=(Ia×R2)/R1.

Outputs from the comparator 131a and the AND circuit 131c become high if the temperature information Va exceeds the temperature threshold T1. The high-level current control signal turns on the switch 149b. As a result, the sum of a current from the second constant current source 149a and a current from the first constant current source 148 becomes the reference current Ia. The reference current Ia increases by the current from the first constant current source 148. Thus, the drive current i also increases in proportion to the reference current Ia.

Outputs from the comparator 131a and 132a and the AND circuits 131c and 132c become high if the temperature information Va exceeds the temperature threshold T2. The high-level current control signals turn on the switches 149b and 150b. As a result, the sum of a current from the first constant current source 148, a current from the second constant current source 149a, and a current from the third constant current source 150a become the reference current Ia. The reference current Ia increases by the currents from the first constant current source 148 and the third constant current source 150a. The drive current i also increases in proportion to the reference current Ia.

All outputs from the comparator 131a to 133a and the AND circuits 131c to 133c become high if the temperature information Va exceeds the temperature threshold T3. The high-level current control signals turn on the switches 149b to 151b. As a result, the sum of currents from all the constant current sources 148, and 149a to 151a becomes the reference current Ia. The drive current i also increases in proportion to the reference current Ia.

When the temperature or the temperature information Va about the semiconductor switching device 110 exceeds the temperature thresholds successively, the reference current Ia increases by the currents from the constant current sources 149a to 151a successively. Thus, the drive current i increases in a stepwise manner as shown in FIG. 19. Similarly, when the temperature of the semiconductor switching device 110 decreases, the temperature information Va decreases in the order of T3, T2, and T1, and the drive current i also decreases in a stepwise manner.

As described above, multiple temperature thresholds for the temperature information Va can be defined to change the drive current I in a stepwise manner. There has been described the configuration of changing the current quantity for the constant current source 147. Further, multiple temperature thresholds may be defined for the temperature information Va in the configurations of changing resistance values as described in the ninth and tenth embodiments. In this case, the resistance value is changed in a stepwise manner to change the drive current i in a stepwise manner. In the present case, the first resistor 143 and the second resistor 144 are coupled in series using multiple resistors, and the switches coupled parallel to the resistors are turned on or off sequentially.

### Twelfth Embodiment

A semiconductor switching device drive apparatus according to a twelfth embodiment of the present disclosure will be described. The semiconductor switching device drive apparatus according to the present embodiment continuously varies the drive current i.

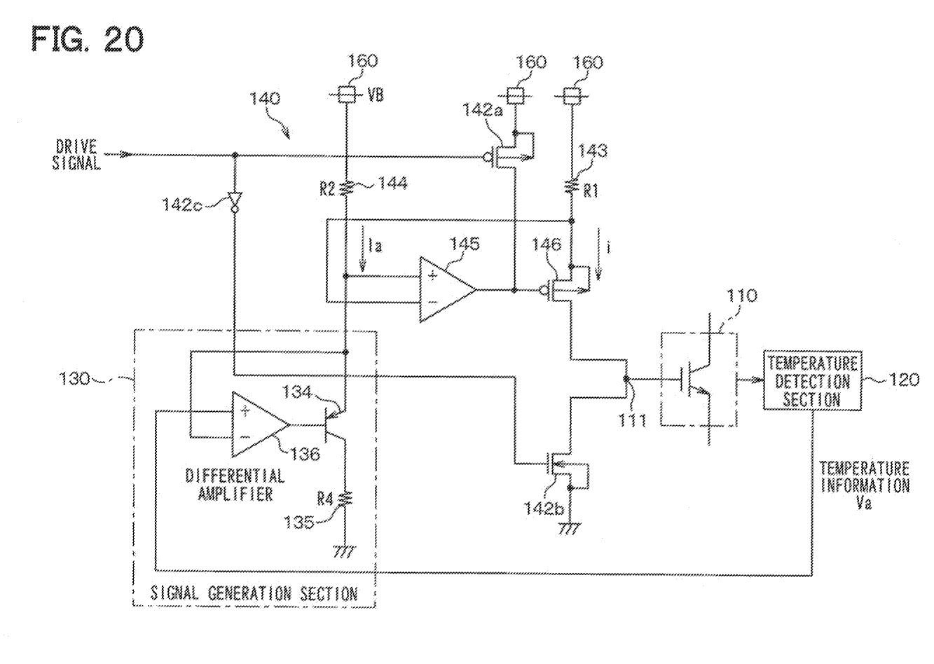

As shown in FIG. 20, a signal generation section 130 according to the present embodiment includes a transistor 134, a resistor 135, and a differential amplifier 136.

The transistor 134 is a PNP-type bipolar transistor. The emitter is coupled to the other end of the second resistor 144 in the drive section 140. The collector is coupled to the resistor 135. The base of the transistor 134 is coupled to an output terminal of the differential amplifier 136. The resistor 135 is coupled between the transistor 134 and the ground.

The differential amplifier 136 drives the transistor 134 as follows. At the non-inverting input terminal (+), the differential amplifier 136 is supplied with the temperature information Va as a reference voltage output from the temperature detection section 120. At the inverting input terminal (−), the differential amplifier 136 is supplied with a voltage on the emitter side and outputs differential amplification between the inputs.

In the signal generation section 130 according to the present embodiment, the voltage on the emitter side of the transistor 134 corresponds to the current control signal. In other words, the signal generation section 130 is supplied with a detection result from the temperature detection section 120 and outputs a current control signal with continuously varying magnitude based on the detection result.

The drive section 140 according to the present embodiment does not includes the constant current source 147, which is included in the drive section 140 shown in FIG. 13 according to the eighth embodiment, for example. The signal generation section 130 is coupled to the second resistor 144 and the operational amplifier 145.

The semiconductor switching device drive apparatus according to the present embodiment continuously varies the temperature information Va, thereby continuously varying an output from the differential amplifier 136. The reference current Ia continuously varies in accordance with the temperature information Va. The value Ia in the drive current i=(Ia×R2)/R1 continuously varies. The drive current i also continuously varies. Specifically, increasing the temperature information Va also increases an output from the differential amplifier 136. The reference current Ia increases accordingly.

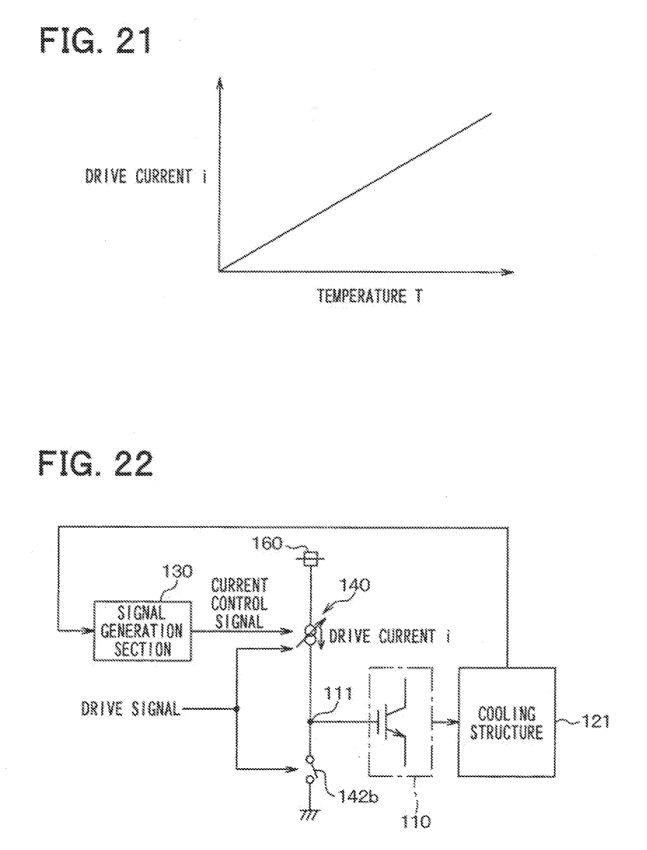

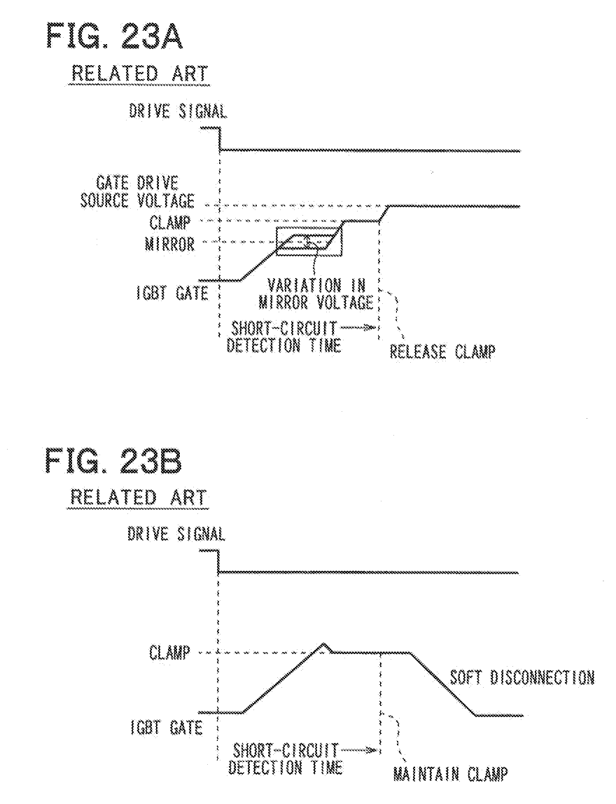

As shown in FIG. 21, the temperature and the drive current i of the semiconductor switching device 110 have a proportionate relationship. Increasing the temperature of the semiconductor switching device 110 increases the drive current i at a predetermined gradient.

According to the present embodiment, the temperature information Va from the temperature detection section 120 is used as the reference voltage. The gate of the transistor 134 receives an output from the differential amplifier 136. The source of the transistor 134 feeds an input back to the differential amplifier 136. The reference current Ia continuously varies. The drive section 140 can continuously vary the drive current i supplied to the control terminal 111 based on the current control signal with continuously varying magnitude. The drive current can be fine-tuned.

In the present embodiment, the differential amplifier 136 can operate as an output section.

### Thirteenth Embodiment

A semiconductor switching device drive apparatus according to a thirteenth embodiment of the present disclosure will be described. The first to twelfth embodiments use the temperature-sensitive device as the temperature detection section 120. The semiconductor switching device drive apparatus according to the present embodiment uses a cooling structure.

A heat-radiating switching device such as the semiconductor switching device 110 dissipates heat using a cooling structure so as to restrict the semiconductor switching device 110 from overheating.

As shown in FIG. 22, the semiconductor switching device drive apparatus according to the present embodiment includes a cooling structure 121. The cooling structure 121 is provided with a temperature sensor (not shown). A detection signal output from the temperature sensor can be used as the temperature information Va. The temperature sensor detects the temperature of the cooling structure 121 to indirectly detect the temperature of the semiconductor switching device 110.

The cooling structure 121 may be designed for water cooling or air cooling. For the water cooling, the temperature sensor just needs to detect the water temperature. For the air cooling, the temperature sensor just needs to detect the air temperature. That is, the temperature sensor just needs to detect the temperature of the cooling medium.

The semiconductor switching device 110 can use the cooling structure 121 as well as the temperature-sensitive device for temperature detection.

In the present embodiment, the cooling structure 121 can operate as a temperature detection section.

The semiconductor switching device drive apparatus according to the eighth to thirteenth embodiments have the temperature-sensitive device or the cooling structure 121 as examples of detecting the temperature of the semiconductor switching device 110. A resistor such as a thermistor may also be used.

In the above-described embodiments, the first changeover switch 142a and the second changeover switch 142b are included in the drive section 140 as an example. The drive section 140, the first changeover switches 142a, and the second changeover switch 142b may be configured differently from each other.

It may be possible to appropriately define at which level (e.g., low or high level) of signals the switches described in the above-described embodiments are turned on or off. It may be also possible to appropriately define meanings of the signal levels.

What is claimed is:

1. A load drive apparatus comprising:
a switching device that controls an on-off state of current supply to a load;
a gate drive circuit that turns on the switching device and supplies current to the load by controlling a gate voltage of the switching device so that the switching device operates in a full-on state where the switching device is in an unsaturated region;
a clamp circuit that clamps the gate voltage of the switching device to a clamp voltage lower than the gate voltage in the full-on state and higher than a mirror voltage;
a temperature detection circuit that detects a temperature of the switching device; and
an arithmetic device that calculates a voltage corresponding to a variation in the mirror voltage based on the temperature detected by the temperature detection circuit and controls the clamp voltage in the clamp circuit so as to be the calculated voltage.

2. The load drive apparatus according to claim 1, wherein
the switching device includes a temperature-sensitive diode, and
the temperature detection circuit detects the temperature of the switching device using an output signal from the temperature-sensitive diode as temperature information.

3. The load drive apparatus according to claim 1, further comprising
a cooler that cools the switching device and includes a temperature sensor, wherein
the temperature sensor detects a temperature of a cooling medium that flows in the cooler, and
the temperature detection circuit detects the temperature of the switching device using a detection signal from the temperature sensor as temperature information.

4. A load drive apparatus comprising:
a switching device that controls an on-off state of current supply to a load;
a gate drive circuit that turns on the switching device and supplies current to the load by controlling a gate voltage of the switching device so that the switching device operates in a full-on state where the switching device is in an unsaturated region;
a clamp circuit that clamps the gate voltage of the switching device to a clamp voltage lower than the gate voltage in the full-on state and higher than a mirror voltage;
a current detection circuit that detects an output current supplied from the switching device to the load; and
an arithmetic device that calculates a voltage corresponding to a variation in the mirror voltage based on the output current supplied from the switching device and detected by the current detection circuit and controls the clamp voltage in the clamp circuit so as to be the calculated voltage.

5. The load drive apparatus according to claim 4, wherein
the switching device includes a sense terminal, and
the current detection circuit detects the output current from the switching device using a sense current that flows through the sense terminal as current information.

6. The load drive apparatus according to claim 4, further comprising
a current detection portion that generates an output signal in accordance with the output current from the switching device, wherein
the current detection circuit detects the output current from the switching device using the output signal from the current detection portion as current information.

7. A load drive apparatus comprising:
a switching device that controls an on-off state of current supply to a load;
a gate drive circuit that turns on the switching device and supplies current to the load by controlling a gate voltage of the switching device so that the switching device operates in a full-on state where the switching device is in an unsaturated region;
a clamp circuit that clamps the gate voltage of the switching device to a clamp voltage lower than the gate voltage in the full-on state and higher than a mirror voltage;
a mirror voltage detection circuit that detects the mirror voltage by detecting a gate voltage of the switching device applied to the load; and
an arithmetic device that calculates a voltage corresponding to a variation in the mirror voltage based on the mirror voltage detected by the mirror voltage detection circuit and controls the clamp voltage in the clamp circuit so as to be the calculated voltage.

8. A load drive apparatus comprising:
a switching device that includes a first electrode and a second electrode and controls an on-off state of a currently supply line to a load when a gate voltage is controlled, the first electrode coupled to a power supply side of the current supply line, the second electrode coupled to a reference point side of the current supply line;
a gate drive circuit that turns on the switching device and supplies current to the load by controlling the gate voltage of the switching device so that the switching device operates in a full-on state where the switching device is in an unsaturated region;
a clamp circuit that clamps the gate voltage of the switching device to a clamp voltage lower than the gate voltage in the full-on state and higher than a mirror voltage;
a switch that short-circuits between a gate and a collector of the switching device;
a constant current source that generates a constant current in order to drive the switching device at a constant current;
a voltage detection circuit that short-circuits between the gate and the collector of the switching device using the switch, drives the switching device at the constant current generated by the constant current source, and detects a voltage between the gate and the second electrode of the switching device; and
an arithmetic device that learns at least one of a variation in a gate threshold voltage and a variation in a current amplification factor based on the voltage between the gate and the second electrode detected by the voltage detection circuit, calculates a voltage corresponding to a variation in the mirror voltage based on a learning result, and controls the clamp voltage in the clamp circuit so as to be the calculated voltage.

9. A semiconductor switching device arrive apparatus comprising:
a semiconductor switching device including a control terminal;
a drive section that supplies a drive current to the control terminal of the semiconductor switching device, the drive section configured so that an on-time that elapses until the semiconductor switching device is turned on shortens with increase in magnitude of the drive current;
a control section that controls an on-off state of the semiconductor switching device by allowing or disallowing supply of the drive current from the drive section to the control terminal; and
a temperature detection section that detects one of a device temperature of the semiconductor switching device and an ambient temperature of the semiconductor switching device,
wherein the drive section varies the magnitude of the drive current supplied to the control terminal in accordance with one of the device temperature and the ambient temperature detected by the temperature detection section.

10. The semiconductor switching device drive apparatus according to claim 9, further comprising:
a signal generation section that receives a detection result from the temperature detection section and outputs a current control signal in accordance with the detection result, the current control signal being used to vary the magnitude of the drive current supplied to the control terminal of the semiconductor switching device; and
a variable resistor coupled between a power source and the control terminal,
wherein the drive section supplies the control terminal with the drive current that flows to the variable resistor and varies the magnitude of the drive current supplied to the control terminal by varying a resistance value of the variable resistor.

11. The semiconductor switching device drive apparatus according to claim 9, further comprising
a signal generation section that receives a detection result from the temperature detection section and outputs a current control signal in accordance with the detection result, the current control signal being used to vary the magnitude of the drive current supplied to the control terminal of the semiconductor switching device,
wherein the drive section includes a variable resistor in which a reference circuit flows and an output section,
wherein the variable resistor is coupled with a power source,
wherein the output section outputs one of a comparison result and a difference between the reference current and the drive current supplied to the control terminal,
wherein the drive section varies the magnitude of the drive current supplied to the control terminal by varying a resistance value of the variable resistor in accordance with the current control signal and varying output from the output section.

12. The semiconductor switching device drive apparatus according to claim 9, further comprising
a signal generation section that receives a detection result from the temperature detection section and outputs a current control signal in accordance with the detection result, the current control signal being used to vary the magnitude of the drive current supplied to the control terminal of the semiconductor switching device,
wherein the drive section includes a current source in which a variable reference current flows and a current comparison section,
wherein the current comparison section compares the reference current with the drive current supplied to the control terminal, and
wherein the drive section varies the magnitude of the drive current supplied to the control terminal by varying the reference current in accordance with the current control signal and varying an output of the output section.

13. The semiconductor switching device drive apparatus according to claim 10,
wherein the signal generation section includes a temperature comparison section that compares a detection result of the temperature detection section with at least one temperature threshold and outputs a comparison result, and
wherein the drive section varies the drive current supplied to the control terminal based on the comparison result of the temperature comparison section.

14. The semiconductor switching device drive apparatus according to claim 10,
wherein the signal generation section includes an output section that receives a detection result from the temperature detection section and outputs a current control signal whose magnitude continuously varies with the detection result, and
wherein the drive section continuously varies the drive current supplied to the control terminal based on the current control signal whose magnitude continuously varies.
